(19) United States
(12) Patent Application Publication
(10) Pub. No.: US 2009/0146151 A1
(43) Pub. Date: Jun. 11, 2009

(54) THIN FILM TRANSISTOR ARRAY SUBSTRATE AND METHOD OF MANUFACTURING THE SAME

(75) Inventor: Qiqi SHEN, Shanghai (CN)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: SVA OPTRONICS

(21) Appl. No.: 12/327,755

(22) Filed: Dec. 3, 2008

(30) Foreign Application Priority Data
Dec. 5, 2007 (CN) 200710171791.4

(51) Int. Cl. H01L 31/18; H01L 21/3205

(52) U.S. Cl. 257/59; 438/586; 257/E31.003; 257/E21.411

(57) ABSTRACT

A method for manufacturing a TFT-array substrate includes forming a first conductive pattern layer including a gate line, a gate electrode, and a lower gate pad electrode using a first mask, forming a channel and a second conductive pattern layer including a source electrode, a drain electrode, a data line, a data pad electrode, and a middle gate pad electrode using a second mask, and forming a third conductive pattern layer including a pixel electrode, an upper gate pad electrode, and an upper data pad electrode using a third mask. A TFT-array substrate includes crossing gate lines and data lines, TFTs formed at the crossings of gate lines and data lines, pixel electrodes formed in regions defined by the crossing gate lines and data lines, data pad electrodes connected to the data lines, and gate pad electrodes connected to the gate lines.

### CROSS REFERENCE TO RELATED APPLICATIONS

This application claims the benefit of Chinese Patent Application No. 200710171791.4 filed on Dec. 5, 2007, which is incorporated by reference herein for any purpose.

### TECHNICAL FIELD

The present invention relates to a semiconductor device and method of manufacturing the same, and more particularly, to a thin film transistor (TFT) array substrate and method of manufacturing the same.

### BACKGROUND

A liquid crystal display (LCD) device displays an image by controlling the light transmittance of liquid crystal (LC) using an electric field. A thin film transistor liquid crystal display (TFT-LCD) is a variant of LCD, which uses TFT to enhance image quality. A TFT-LCD drives liquid crystal using an electric field between a pixel electrode and a common electrode, which are disposed on an upper substrate and a lower substrate, respectively. A TFT-LCD device includes a TFT array substrate (lower array substrate) and a color filter array substrate (upper array substrate) facing each other, a spacer disposed between the two array substrates to maintain a cell gap, and liquid crystal filling the cell gap. The TFT array substrate includes signal lines, TFTs, and an alignment layer coated thereon to align the LC.

The TFT array substrate needs at least four mask processes in mass production in the present time. FIG. 1 is a plane view of a related art wherein a TFT-array substrate is fabricated using a four-mask-process. FIG. 2 is a cross-sectional view taken along line A-A and line B-B in FIG. 1. According to FIGS. 1 and 2, the TFT-array substrate of the related art includes a lower substrate 1, whereon a gate line 11 and a data line 51 crosses each other. The substrate further includes a gate insulating layer 20 between the gate line 11 and the date line 51, and a TFT 91 at the crossing of the gate line 11 and the data line 51. The TFT 91 includes a gate electrode 10, a source electrode 52 and a drain electrode 53. The gate electrode 10 is connected to the gate line 11. And the source electrode 52 is connected to the data line 51. The TFT 91 also includes a semiconductor layer 30 overlapping the gate electrode 10, wherein the semiconductor layer forms a channel between the source electrode 52 and the drain electrode 53. The substrate also includes a pixel electrode 70 in a pixel region defined by the crossing of the gate line 11 and the data line 51. The pixel electrode 70 is connected to the drain electrode 53 through a contacting hole 61. The gate line 11 is connected to a gate pad electrode 12. The data line 51 is connected to a data pad electrode 54. The substrate also includes an ohmic contact layer 40 on the semiconductor layer 30 to provide an ohmic contact with the data line 51, the source electrode 52, the drain electrode 53, and the data pad electrode 54.

A method of manufacturing a TFT-array substrate of a liquid crystal panel using a four-mask process will be briefly described below, in connection with FIGS. 3A to 3D.

As depicted in FIG. 3A, a first conductive pattern group including a gate line 11 (in FIG. 1), a gate electrode 10 and a lower gate pad electrode 12 is formed on a lower substrate using a first mask process.

As depicted in FIG. 3B, a gate insulating layer 20, a semiconductor layer 30, and an ohmic contact layer 40 are formed sequentially on the substrate where the gate pattern is formed. A second conductive layer 50 is then deposited on the ohmic contact layer 40. Thereafter, patterns of the semiconductor layer 30 and ohmic contact layer 40 are formed on the gate insulating layer 20 using a second mask. A second conductive pattern group including a data line 51 (FIG. 1), source electrode 52, a drain electrode 53, and a lower data pad electrode 54 are formed on the gate insulating layer 20 in the second mask process.

As depicted in FIG. 3C, after the second conductive pattern layer is formed, a passivation layer 60 is formed on the lower substrate by a deposition (PECVD). The passivation layer 60 is patterned through a third mask process, using lithography and etching, to form contact hole 61.

As depicted in FIG. 3D, after the contact holes 61 are formed, a transparent conductive layer 70 is formed on the lower substrate by a deposition, and a third conductive pattern group including a pixel electrode 70, an upper gate pad electrode 72 and an upper data pad electrode 71 is formed on the passivation layer 60 using a fourth mask process.

The manufacture of a TFT-array substrate is complicated and expensive due to the requirement of a semiconductor process and several mask processes. Each mask process includes several sub-processes such as thin film deposition, clean, etching, stripping, etc.

In order to simplify the process and lower the cost, a method of manufacturing a thin film transistor array substrate which can reduce the number of mask processes is desired.

### SUMMARY

A primary objective of the invention is to provide a method of manufacturing a thin film transistor array substrate which can reduce the number of mask processes by using multi-gray masks.

A secondary objective of the invention is to provide a TFT-array substrate manufactured using the method mentioned above, comprising a gate pad with three layers of metal, which effectively reduces the corrosion of the gate pad.

The invention includes a thin film transistor array substrate and a method for manufacturing the same. The method includes providing a substrate, and forming a first metal layer on the substrate. A first photo resist pattern layer is deposited on the first metal layer using a first mask, wherein the first photo resist pattern layer covering a gate pad electrode region has a first height, and the first photo resist pattern layer covering a gate line region and a gate electrode region has a second height, the first height being greater than the second height. The height of the first photo resist pattern layer is reduced (e.g., by the second height) to expose the gate line and the gate electrode covered by the first photo resist pattern layer with the second height. A gate insulating layer, a semiconductor layer, and an ohmic contact layer are sequentially deposited on the substrate. The remaining of the first photo resist pattern layer is removed to expose the lower gate pad electrode covered by the first photo resist pattern layer with the first height. By the above processes, a first conductive pattern layer including a gate line, a gate electrode, and a lower gate pad electrode is formed using the first photo resist pattern layer.

The method further includes depositing a second metal layer on the substrate, and forming a second photo resist pattern layer on the second metal layer using a second mask, wherein the second photo resist pattern layer covering a channel region has a fifth height, the second photo resist pattern layer covering a data line and a source electrode region has a fourth height, the second photo resist pattern layer covering a drain electrode and a gate pad electrode region has a third height, the third height being greater than the fourth height, and the fourth height being greater than the fifth height. The height of the second photo resist pattern layer is then reduced (e.g., by the fifth height), and a part of the second metal layer, the semiconductor layer, and the ohmic contact layer are removed to expose the channel region covered by the photo resist pattern layer with the fifth height. The height of the second photo resist pattern layer is further reduced to expose the data line and source electrode covered by the photo resist pattern layer with the fourth height, and a passivation layer is deposited. The remaining of the second photo resist pattern layer is then removed to expose the drain electrode, the data pad electrode, and the middle gate pad electrode covered by the second photo resist pattern layer with the third height. By the above processes, a channel and a second conductive pattern layer including a source electrode, a drain electrode, a data line, a data pad electrode, and a middle gate pad electrode are formed.

A third conductive pattern layer including a pixel electrode, an upper gate pad electrode, and an upper data pad electrode is then formed using a third mask, wherein the pixel electrode electrically connects to the drain electrode.

The invention also includes a thin film transistor array substrate manufactured using the method as described above. The TFT-array substrate comprises crossing gate lines and data lines, TFTs formed at the crossings of gate lines and data lines, pixel electrodes formed in pixel regions defined by the crossing gate lines and data lines, data pad electrodes connected to the data lines, and gate pad electrodes connected to the gate lines, wherein a gate pad electrode includes a lower gate pad electrode formed on the first metal layer, a middle gate pad electrode formed on the second metal layer, and an upper gate pad electrode formed on the third conductive layer.

### BRIEF DESCRIPTION OF THE DRAWINGS

FIG. 1 is a plane view of a thin film transistor (TFT) array substrate using a four-mask process;

FIG. 2 is a cross-sectional view of the TFT array substrate taken along the lines A-A and B-B of FIG. 1;

FIG. 3A to 3D illustrate a method for manufacturing the TFT-array substrate using the four-mask process;

FIG. 4 is a plane view of a TFT-array substrate in a first mask process of the present invention;

FIG. 5A to 5D are cross-sectional views of the TFT-array substrate in the first mask process and follow-up processes thereof of the present invention;

FIG. 6 is a plane view of a TFT-array substrate in a second mask process of the present invention;

FIG. 7A to 7E are cross-sectional views of the TFT-array substrate in the second mask process and follow-up processes thereof of the present invention;

FIG. 8A is a plane view of a TFT-array substrate in a third mask process of the present invention; and

FIG. 8B is a cross-sectional views of the TFT-array substrate in the third mask process of the present invention.

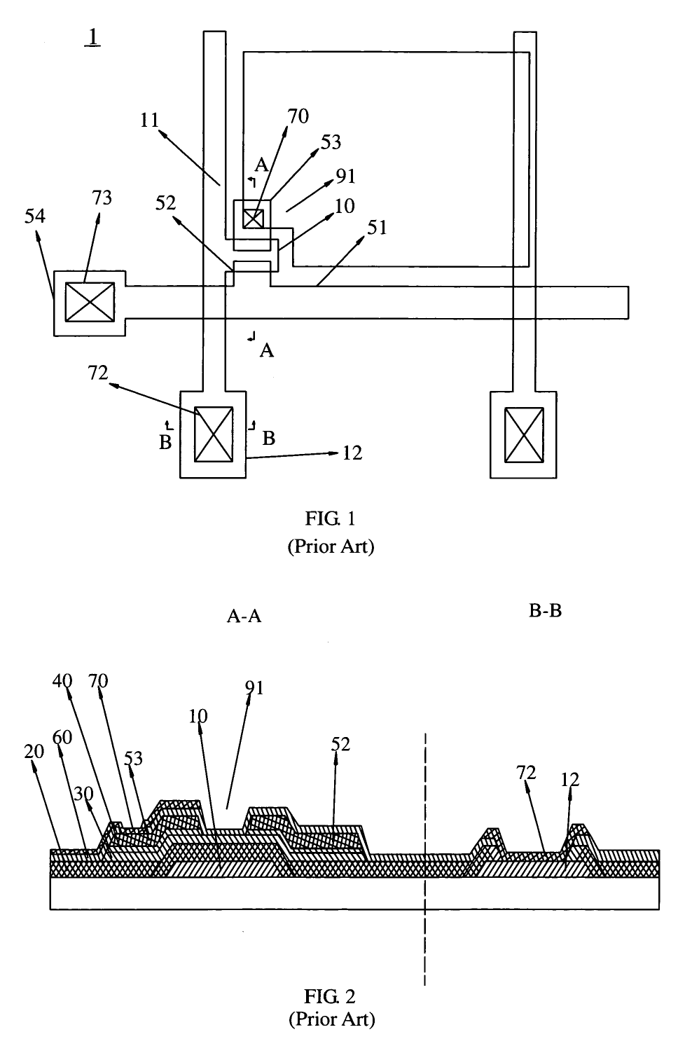

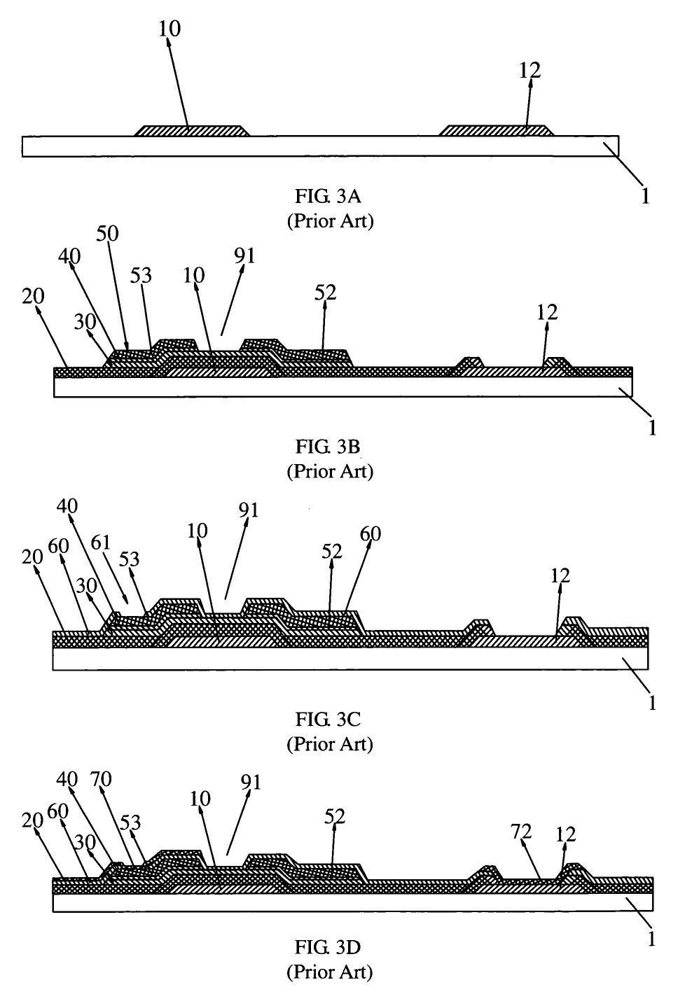

### DESCRIPTION OF THE EMBODIMENTS

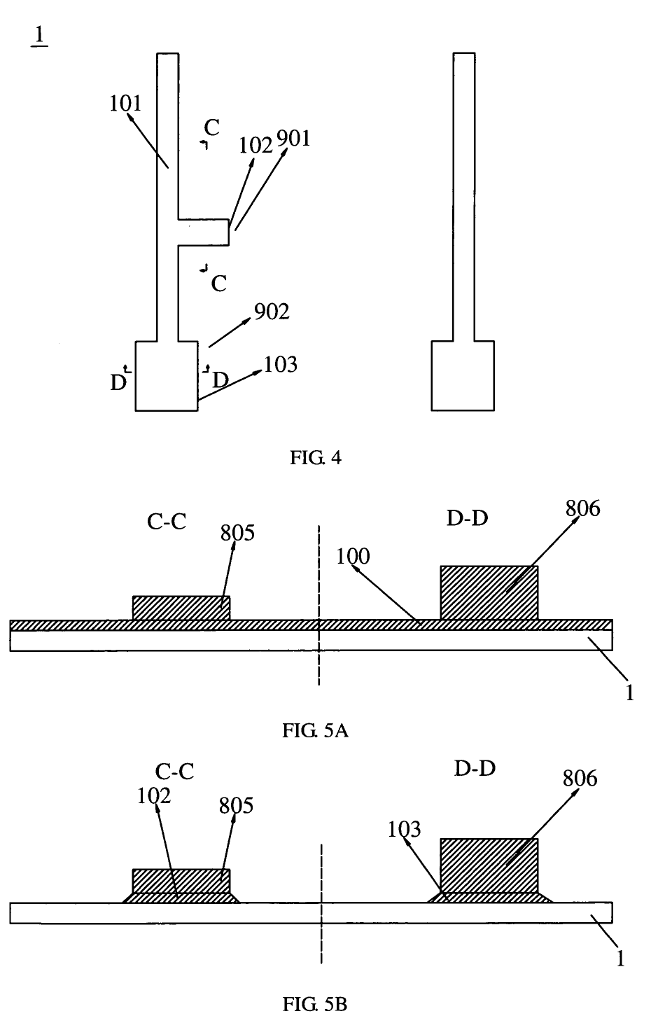

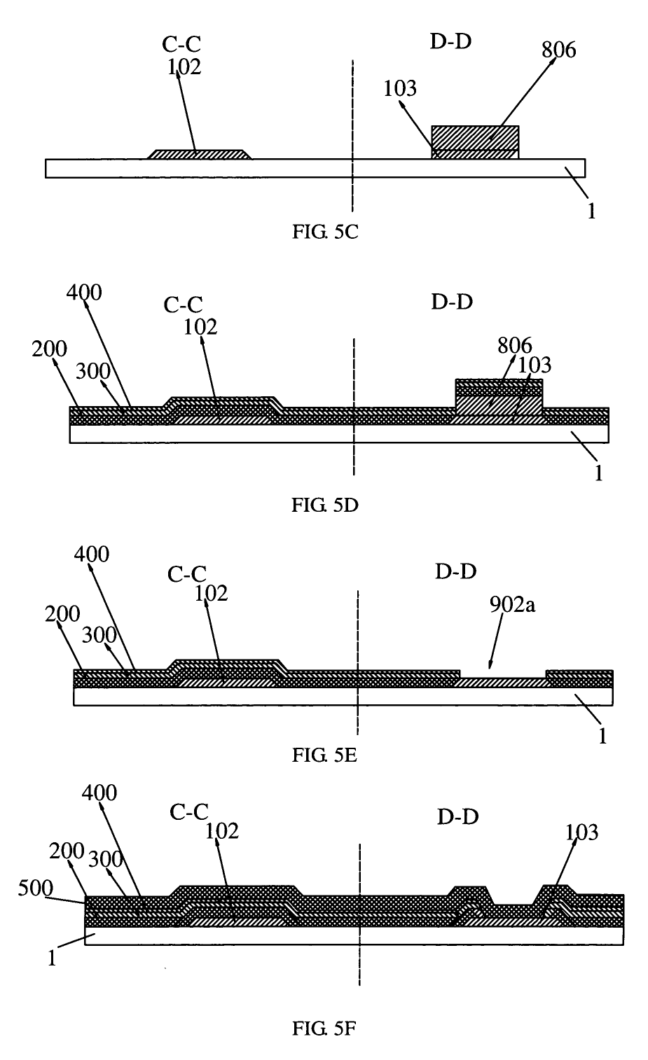

FIG. 4 is a plane view of a TFT-array substrate in a first mask process of the present invention. As depicted in FIG. 4, a first metal pattern layer including a gate line 101, a gate electrode 102, and a lower gate pad electrode 103 is formed on the substrate 1 using a first mask. Detailed steps of the process are shown in FIGS. 5A to 5E. First, referring to FIG. 5A, the first metal layer 100 is formed on the substrate 1 using a sputtering process or other deposition processes. Then a first photo resist pattern is formed on the first metal layer 100 using the first mask. The first mask can be a multi-gray mask with a mask substrate made of a transparent material, a shielding portion for completely shielding light, a semi-transmitting portion for partially transmitting light and partially shielding light which are formed on the mask substrate. After a develop process of the first mask process, a pattern with predetermined steps is formed on the photo resist layer corresponding to the position of shielding region and the semi-transmitting region. The photo resist layer 805 with a second height covers gate line 101 and gate electrode 102, and the photo resist layer 806 with a first height covers the gate pad electrode 103. The first height is greater than the second height. The photo resist can be positive or negative, and the position of different shielding light area can be adjusted based on the material of the photo resist in the process.

Referring to FIG. 5B, a first conductive layer pattern (as shown in FIG. 4) including gate line 101, gate electrode 102 and lower gate pad electrode 103 is formed using the first photo resist pattern layer (as a protection) to remove a part of the first metal layer 100.

Referring to FIG. 5C, in order to expose the gate line 101 and gate electrode 102 covered by the photo resist layer 805, the photo resist pattern 805 with the second height is removed and the height of the photo resist pattern with the first height is reduced. The method to reduce the height of the first photo resist pattern can be an ashing process using oxygen plasma.

Then, referring to FIG. 5D, a gate insulating layer 200, a semiconductor layer 300 and an ohmic contact layer 400 are deposited sequentially on the substrate. Thereafter, referring to FIG. 5E, the remaining first photo resist layer 806 is removed using a stripping-off process. In the mean time, the gate insulating layer 200, the semiconductor layer 300 and the ohmic contact layer 400 which are deposited on the remaining of the first photo resist layer 806 are also removed. As a result, the lower gate pad electrode 103 is exposed, and the gate pad contacting hole 902a is formed. Thereafter, a second metal layer 500 (as shown in FIG. 5F) is deposited to cover gate line 101, gate electrode 102 and lower gate pad electrode 103, and the second metal layer 500 is connected with the lower pad electrode 103 through the gate pad contacting hole 902a.

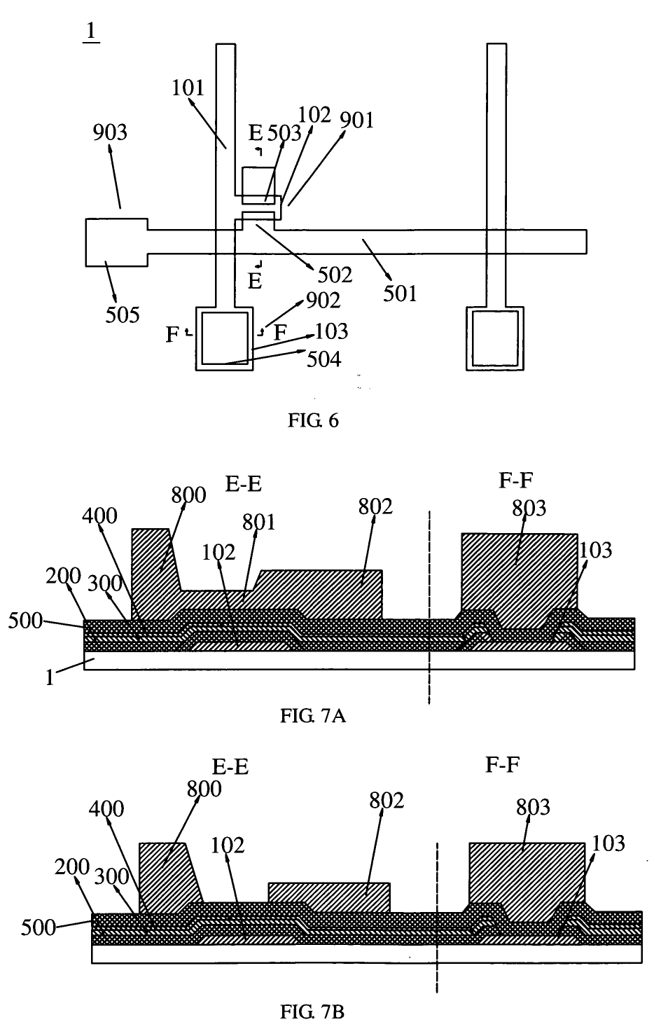

FIG. 6 is a plane view of a TFT-array substrate in the second mask process of the present invention. The second metal layer 500 and the semiconductor layer 300 are patterned to form pre-determined structures using a second mask and an etching process. Thereafter, the pattern of a second semiconductor layer including data line 501, source electrode 502, drain electrode 503, and lower data pad electrode 505 is formed.

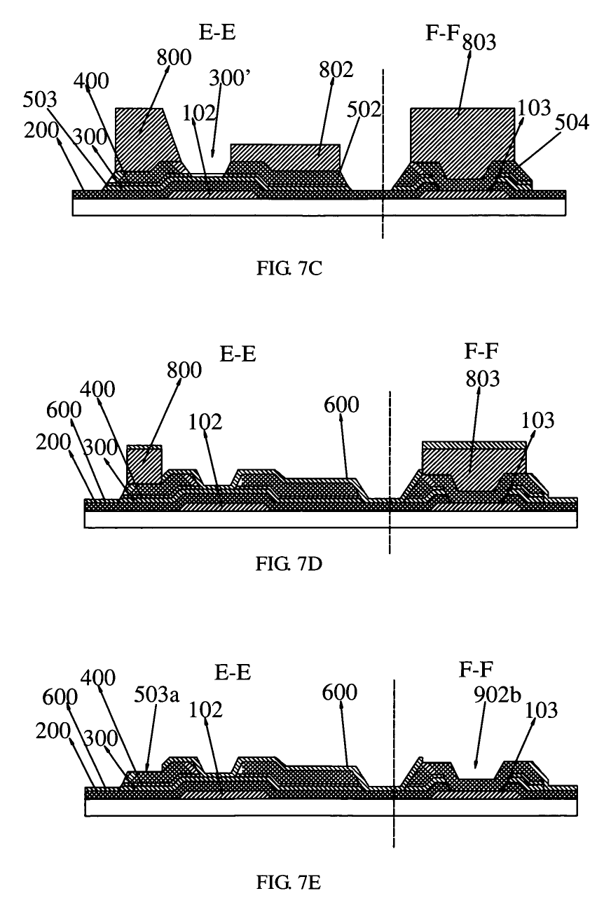

FIG. 7A to 7E show the detailed process flow. Referring to FIG. 7A, a second photo resist pattern is formed on the second metal layer 500 using a second mask. The second mask can be a multi-gray mask (HTM) with a mask substrate made of a transparent material, a shielding portion for completely shielding light, a one-third transmitting portion for shielding two-third of light and a two-third transmitting portion for shielding one-third of light formed on the mask substrate. The one-third and two-third light shielding are merely exemplary embodiments, and other levels of transparency may be used as long as they result in different height of photo resist after developing. After a develop process using the second mask, the photo resist patterns with predetermined steps corresponding to the shielding portion, the one-third transmitting portion, the two-third transmitting portion, and transmitting portion are formed. The photo resist can be positive or negative, and the position of different shielding light portions can be adjusted based on the material of the photo resist in the process.

In one example embodiment, a photo resist layer 801 with a fifth height covers a channel area corresponding to TFT's channel area 300′. A photo resist layer 802 with a fourth height covers the source electrode 502 and data line 501. A photo resist layer 800 and 803 with a third height covers the drain electrode 503 and middle gate pad electrode 504. The third height is greater than the fourth height, and the fourth height is greater than the fifth height.

Referring to FIG. 7B, the second photo resist layer pattern can be used to remove a part of the second metal layer 500, the semiconductor layer 300 and the ohmic contact layer 400 (e.g., by etching). In order to expose the channel area of TFT covered by photo resist layer 801, the photo resist pattern later with the fifth height is removed and the height of the photo resist pattern with the fourth height and third height are reduced. The method to remove the firth-height photo resist can be an ashing process using oxygen plasma.

Referring to FIG. 7C, after the second etching process, the semiconductor layer 300 as the channel 300′ of the TFT's active layer is formed by removing the second metal layer 500 and the ohmic contact layer 400 of the channel area of TFT. The second conductive pattern layer including the source electrode 502, the drain electrode 503 of TFT 901, the data line 501, the lower data pad electrode 505, and the middle gate pad electrode 504 are formed, as shown in FIG. 6.

Referring to FIG. 7D, in order to expose the data line 501 and the source electrode 502 covered by the photo resist layer, the photo resist pattern layer 802 with the fourth height is removed and the height of the photo resist pattern layer 800 and 803 with the third height is reduced. The method to remove the fourth-height photo resist can be an ashing process using oxygen plasma. Thereafter, a passivation layer 600 is deposited on the substrate on which the second semiconductor pattern layer is formed.

Referring to FIG. 7E, by removing, for example, by a stripping-off process, the remaining of the photo resist layer 800 and 803 (and passivation layer 600 thereon) on drain electrode 503, data pad electrode 505, and middle gate pad electrode 504 of the second conductive pattern layer, a drain contacting hole 503a, a contacting hole for data pad electrode 903, a gate pad contacting hole 902b are formed.

After the second mask process, a transparent conductive layer is deposited on the substrate. The transparent conductive layer can be made from ITO, TO, ITZO or IZO.

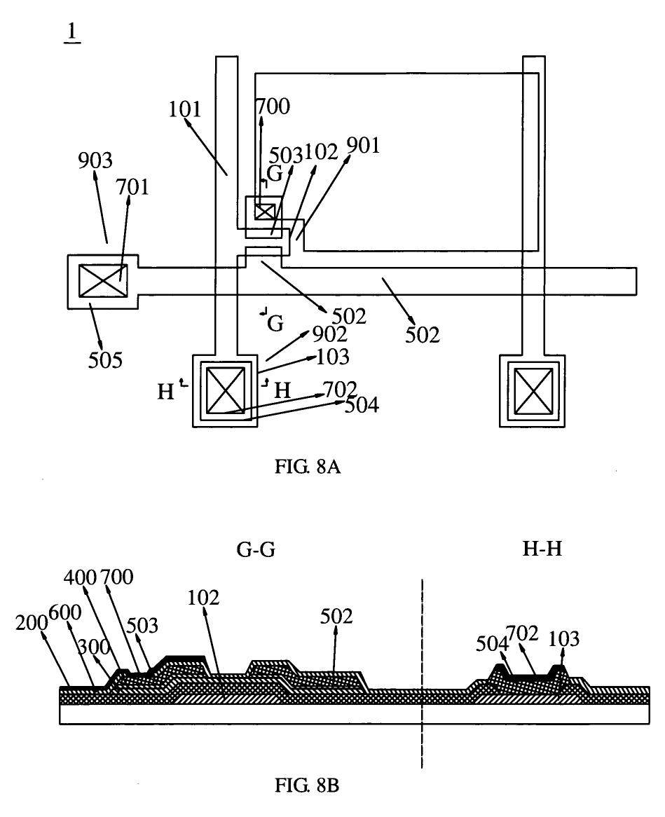

Referring to FIG. 8A to 8B, a third conductive pattern layer including a pixel electrode 700, an upper gate pad electrode 702, and an upper data pad electrode 701 is formed by using a third mask, lithography and etching processes. The pixel electrode 700 is connected to the drain electrode 503 through the contacting hole 503a. The upper gate pad electrode 702 is connected to the middle gate pad electrode 504 formed on the second conductive layer through the contacting hole 902b. The middle gate pad electrode 504 is connected to the lower gate pad electrode 103 via the contacting hole through the gate insulating layer. The upper data pad electrode 701 is connected to the lower data pad electrode 505 and the data line 501 via the contact hole through passivation layer 600.

FIG. 8A is a plane view of a TFT-array substrate according to an exemplary embodiment of the present invention. FIG. 8B is a cross-sectional view of the TFT substrate in FIG. 8A taken along the line G-G and line H-H. Referring to FIGS. 8A and 8B, the TFT substrate includes a lower substrate 1 comprising gate lines 101 and data lines 501 formed on the lower substrate crossing each other with a gate insulating layer 200 in between, a TFT 901 formed at each crossing of gate line 101 and data line 501, a pixel electrode 700 formed in a pixel region defined by the crossing gate and data lines, a data pad electrode 903 connected to the data lines 501, a gate pad electrode 902 connected to the gate lines 101. A storage capacitor is formed by the overlapping area between the gate line 101 and the pixel electrode 700.

TFT 901 includes a gate electrode 102 connected to the gate line 101, a source electrode 502 connected to the data line 501, and a drain electrode 503 connected to the pixel electrode 700. TFT 901 also includes a semiconductor layer 300 that overlaps with the gate electrode 102 and the gate insulating layer 200, and forms a channel 300′ between the source electrode 502 and the drain electrode 503. An ohmic contact layer 400 is further formed on the semiconductor layer 300 that provides an ohmic contact. The pixel electrode 700 formed in a pixel region connects to drain electrode 503 of TFT 901.

Gate pad electrode 902 includes a lower gate pad electrode 103, a middle gate pad electrode 505 and an upper gate pad electrode 702. The upper gate pad electrode 702 formed on the transparent conductive layer connects with the lower gate electrode 103 via the contacting hole through the gate insulating layer 200 and passivation layer 600. The TFT substrate of the present invention includes a gate pad electrode 902 with three layers of metal, which can effectively prevent the corrosion of the gate pad.

The data pad 903 includes a lower data pad electrode 505 extending from the data line 501 and an upper data pad electrode 701. The upper data pad electrode 701 formed on the transparent conductive layer connects with the data lower electrode 505 via the contacting hole through the passivation layer 600.

As described above, compared with the traditional four-mask process, the present invention reduces one mask process, simplifies the manufacturing process of TFT-array substrates, lowers the manufacturing cost of TFT-array substrate, and improves the throughput of TFT-array substrate. Furthermore, the TFT-array substrate made from the above described method includes a gate pad with three layers of metal, which effectively reduces the corrosion of the gate pad.

It will be apparent to those having ordinary skill in the art that various modifications and variations can be made to the disclosed device and method without departing from the scope of the invention. Other embodiments of the invention will be apparent to those having ordinary skill in the art from consideration of the specification and practice of the invention disclosed herein. It is intended that the specification and examples be considered as exemplary only, with a true scope of the invention being indicated by the following claims and their equivalents.

What is claimed is:

1. A method of manufacturing a thin film transistor array substrate, comprising:
providing a substrate, and forming a first metal layer on the substrate;
forming a first photo resist pattern layer on said first metal layer using a first mask, wherein the first photo resist pattern layer covering a gate pad electrode region has a first height, and the first photo resist pattern layer covering a gate line region and a gate electrode region has a second height, wherein the first height is greater than the second height;
removing a part of the first photo resist pattern layer to expose the gate line and the gate electrode covered by the first photo resist pattern layer with the second height;
depositing a gate insulating layer, a semiconductor layer, and an ohmic contact layer sequentially on the substrate;
removing the remaining of the first photo resist pattern layer to expose a lower gate pad electrode covered by the first photo resist pattern layer with the first height;
depositing a second metal layer on the substrate;
forming a second photo resist pattern layer on the second metal layer using a second mask, wherein the second photo resist pattern layer covering a channel region has a fifth height, the second photo resist pattern layer covering a data line and a source electrode region has a fourth height, the second photo resist pattern layer covering a drain electrode and the gate pad electrode region has a third height, wherein the third height is greater than the fourth height, and the fourth height is greater than the fifth height;
removing a part of the second photo resist pattern layer, a part of the second metal layer, the semiconductor layer, and the ohmic contact layer using the second photo resist pattern layer, to expose the channel region covered by the photo resist pattern layer with the fifth height;
further removing a part of the second photo resist pattern layer to expose the data line and source electrode covered by the photo resist pattern layer with the fourth height, and depositing a passivation layer;
removing the remaining of the second photo resist pattern layer to expose the drain electrode and a middle gate pad electrode covered by the second photo resist pattern layer with the third height; and
forming a pixel electrode and an upper gate pad electrode using a third mask, wherein the pixel electrode electrically connects to the drain electrode.

2. A method of claim 1, wherein the first mask is a multi-gray mask.

3. A method of claim 1, wherein the second mask is a multi-gray mask.

4. A method of claim 1, wherein removing a part of the first photo resist pattern layer includes an ashing process using oxygen plasma.

5. A method of claim 1, wherein removing a part of the second photo resist pattern layer includes an ashing process using oxygen plasma.

6. A method of claim 1, wherein removing the remaining of the first photo resist pattern layer includes a stripping-off process.

7. A method of claim 1, wherein removing the remaining of the second photo resist pattern layer includes a stripping-off process.

8. A thin film transistor array substrate manufactured using the method of claim 1, comprising crossing gate lines and data lines, TFTs formed at the crossings of gate lines and data lines, pixel electrodes formed in pixel regions defined by the crossing gate lines and data lines, and gate pad electrodes connected to the gate lines, wherein a gate pad electrode includes a lower gate pad electrode formed on the first metal layer, a middle gate pad electrode formed on the second metal layer, and an upper gate pad electrode formed on the third conductive layer.
